(19) United States
(12) Patent Application Publication
(10) Pub. No.: US 2012/0153330 A1
(43) Pub. Date: Jun. 21, 2012

(54) LIGHT EMITTING DEVICE AND METHOD OF MANUFACTURING THEREOF

(76) Inventor: Tsuyoshi TSUTSUI, Suwon (KR)

(21) Appl. No.: 13/313,402

(22) Filed: Dec. 7, 2011

(30) Foreign Application Priority Data
Dec. 15, 2010 (KR) 10-2010-0128345

(51) Int. Cl. H01L 33/50; H01L 33/60

(52) U.S. Cl. 257/98; 438/29; 257/E33.061; 257/E33.072

(57) ABSTRACT

A light emitting device and a method of manufacturing thereof are disclosed. The light emitting device includes a light emitting element having first and second main surfaces opposed to each other; a wavelength converting part formed on the first main surface of the light emitting element; first and second terminals formed on the second main surface of the light emitting element; and a reflecting part formed to cover at least sides of the light emitting element and sides of the wavelength converting part. The light emitting device in which the color dispersion of white light is minimized with respect to the emitting direction of light, whereby the white light exhibits uniform characteristics and further, light emitting efficiency is improved is obtained.

### CROSS-REFERENCE TO RELATED APPLICATIONS

This application claims the priority of Korean Patent Application No. 10-2010-0128345 filed on Dec. 15, 2010, in the Korean Intellectual Property Office, the disclosure of which is incorporated herein by reference.

### BACKGROUND OF THE INVENTION

1. Field of the Invention

The present invention relates to a light emitting device and a method of manufacturing thereof.

2. Description of the Related Art

In general, a light emitting diode (LED), a kind of semiconductor light emitting device, is semiconductor device capable of generating light of various colors due to recombination between electrons and electron holes in the junction portion of p-type and n-type semiconductors. The demand for this type of light emitting diode has been continuously increasing because the light emitting diode has various advantages, such as long lifespan, low power consumption, superior initial operating characteristics, high vibration resistance or the like, as compared to a light emitting structure based on a filament. In particular, a group III-nitride semiconductor capable of emitting blue light within a short wavelength region has recently come to prominence.

In general, a light emitting diode may be mounted on a substrate in the state of a chip or package to be used as a light emitting module. This light emitting module includes a fluorescent material or the like, thereby obtaining light of a different wavelength from that of the light emitted from the light emitting diode. Through this fluorescent material, the emitting of white light may be realized. However, even in the case of light emitting diodes having the same characteristics, a position or a degree of thickness in which the fluorescent material is applied may not be constant, thereby leading to white light having different characteristics, whereby color dispersion may occur.

### SUMMARY OF THE INVENTION

An aspect of the present invention provides a light emitting device in which the color dispersion of white light is minimized with respect to the emitting direction of light, whereby the white light exhibits uniform characteristics, and further, light emitting efficiency is improved.

An aspect of the present invention also provides a method of effectively manufacturing the light emitting device. According to an aspect of the present invention, there is provided a light emitting device, including: a light emitting element having first and second main surfaces opposed to each other; a wavelength converting part formed on the first main surface of the light emitting element; first and second terminals formed on the second main surface of the light emitting element; and a reflecting part formed to cover at least sides of the light emitting element and sides of the wavelength converting part.

The reflecting part may be formed to cover the second main surface of the light emitting element.

The reflecting part maybe formed to cover sides of the first and second terminals.

The wavelength converting part may have a thin film shape.

One surface of the wavelength conversion part and one surface of the reflecting part may form a co-plane.

One surfaces of the first and second terminals and one surface of reflecting part may form a co-plane.

The first and second terminals may be the first and second terminals are symmetrically disposed about the center, when the second main surface is viewed in a planar manner.

The reflecting part may include a resin and a reflective filler dispersed in the resin.

According to another aspect of the present invention, there is provided a method of manufacturing a light emitting device, the method including: forming first and second terminals on one surface of a light emitting element; forming a wavelength converting part on the other surface of the light emitting element, the other surface being disposed to be opposite to the first and second terminals; and forming a reflecting part to cover sides of the light emitting element and sides of the wavelength converting part.

The forming of the first and second terminals on one surface of the light emitting element may include forming each of the first and second terminals for individual light emitting element units on one surface of a light emitting laminate, and dividing the light emitting laminate into individual light emitting element units.

The forming of the wavelength converting part may include forming one wavelength converting part for each light emitting element unit and attaching the light emitting element unit to the wavelength converting part corresponidng to the light emitting element unit.

The forming of one wavelength converting part for each light emitting element unit may include cutting the wavelength converting part integrally formed into each light emitting element unit and transferring the cut wavelength converting part onto a UV sheet.

The forming of the reflecting part may include integrally forming the reflecting part with respect to the individual light emitting element units and dividing the reflecting part into individual light emitting element units.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross sectional view schematically showing a light emitting device according to an exemplary embodiment of the present invention;

FIG. 2 is a cross sectional view schematically showing example of a light emitting element in the light emitting device of FIG. 1;

FIG. 3 is a plan view schematically showing an example of a terminal structure in the light emitting device of FIG. 1;

FIG. 4 is an enlarged view schematically showing a wavelength converting part and a circumferential area thereof in the light emitting device of FIG. 1;

FIGS. 5 through 11 are cross sectional views of processes schematically showing a method of manufacturing of a light emitting device according to an exemplary embodiment of the present invention; and

FIG. 12 is a configuration diagram schematically showing an example of using the light emitting device according to the exemplary embodiment of the present invention.

### DETAILED DESCRIPTION OF THE PREFERRED EMBODIMENT

Exemplary embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and sizes of components are exaggerated for clarity. The same or equivalent elements are referred to by the same reference numerals throughout the specification.

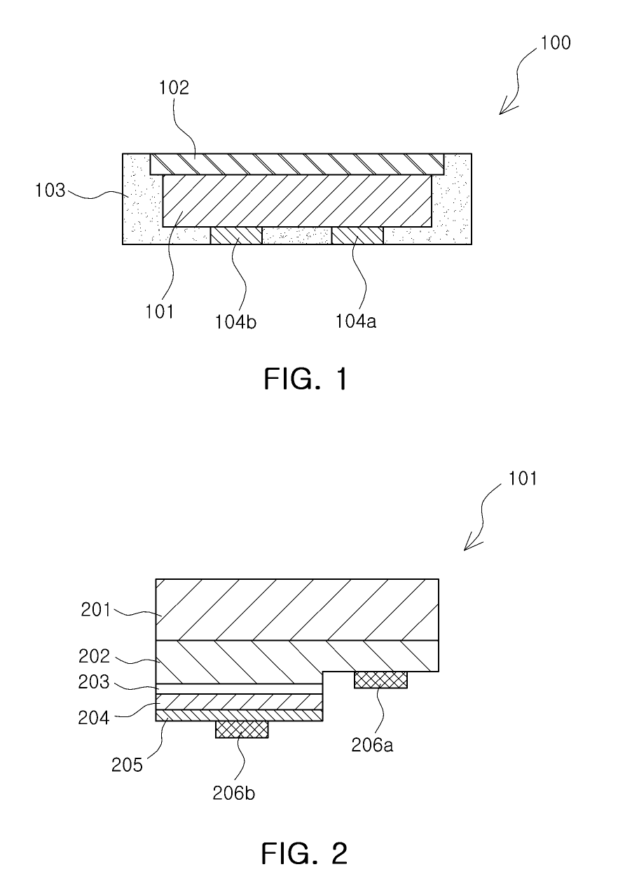

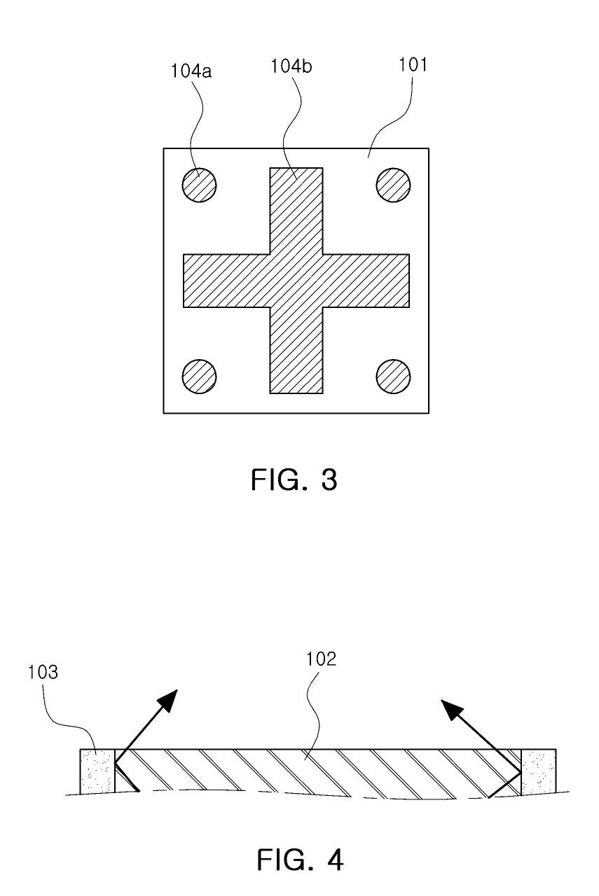

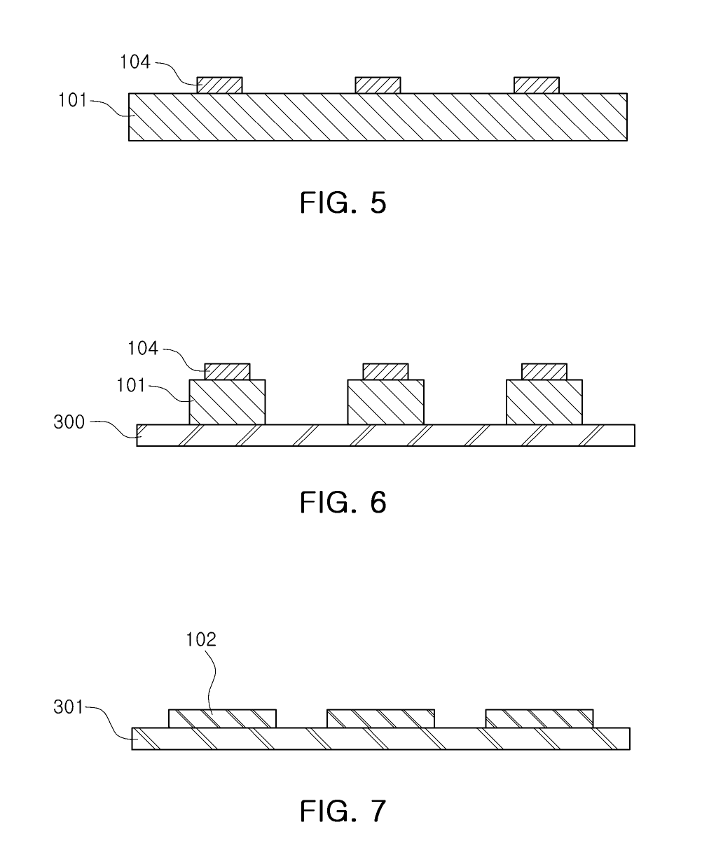

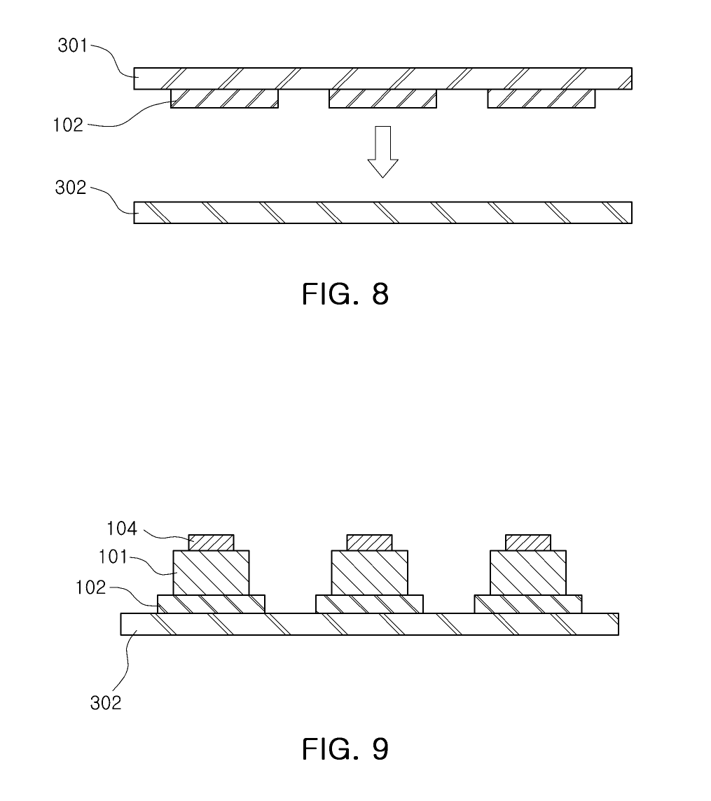

FIG. 1 is a cross sectional view schematically showing a light emitting device according to an exemplary embodiment of the present invention. FIG. 2 is a cross sectional view schematically showing example of a light emitting element in the light emitting device of FIG. 1. FIG. 3 is a plan view schematically showing an example of a terminal structure in the light emitting device of FIG. 1. FIG. 4 is an enlarged view schematically showing a wavelength converter and a circumferential area thereof in the light emitting device of FIG. 1. First, referring to FIG. 1, a light emitting device 100 according to the exemplary embodiment of the present invention includes a light emitting element 101, a wavelength converting part 102, a reflecting part 103, and terminals 104A and 104B. With reference to relationships between individual components, the light emitting element 101 may include first and second main surfaces opposed to each other. In this case, the wavelength converting part 102 is formed on the first main surface (an upper surface of light emitting element 101 of FIG. 1), the first and second terminals 104A and 104B are formed on the second main surface (a lower surface of light emitting element 101 of FIG. 1), and the reflecting part 103 is formed to cover the sides of the light emitting element 101 and the sides of the wavelength converting part 102.

As the light emitting element 101, any element capable of emitting light may be used, and a light emitting diode (LED) may be used therefor. In this case, as shown in FIG. 2, the light emitting element 101 may have a laminated structure including first and second conductive semiconductor layers 202 and 204, and an active layer 203 disposed therebetween. In this case, a substrate 201 for growing a semiconductor may be used, and in some cases, the substrate 201 for growing a semiconductor may be excluded. In the exemplary embodiment of the present invention, the first and second conductive semiconductor layers 202 and 204 may be p-type and n-type semiconductor layers, respectively, or may be made of a nitride semiconductor, for example, AlₓIn_{y}Ga_{(1-x-y)}N (0≦x≦1, 0≦y≦1, 0≦x+y≦1). However, besides the nitride semiconductor, a GaAs based semiconductor or a Gap based semiconductor may be used. The active layer 203 formed between the first and second conductive semiconductor layers 202 and 204 may emit light having a predetermined level of energy due to recombination between electrons and electron holes, and may have a multiple quantum-well structure in which quantum wells and quantum barrier layers are alternatively stacked. In the case of the multiple quantum-well structure, an InGaN/GaN structure may be used.

In addition, the light emitting element 101 may include an ohmic contact part 205 forming an ohmic contact between the second conductive semiconductor layer 204 and the light emitting element 101. In the exemplary embodiment of the present invention, the ohmic contact part 205 may be made of a material having high reflexibility, such as Ag, Ni, Al, Rh, Pd, Ir, Ru, Mg, Zn, Pt, Au or the like, in view of the fact that light emitted from the active layer 203 may be emitted upwardly, that is, in the direction of the substrate 201. However, the ohmic contact part 205 is not an essential constitution, and may be excluded or replaced with another layer. In addition, the light emitting element 101 may include first and second electrodes 206A and 206B electrically connected to the first and second conductive semiconductors 202 and 204, respectively. The first and second electrodes 206A and 206B may be respectively connected with the first and second terminals 104A and 104B in the light emitting device 100 of FIG. 1. The first and second electrodes 206A and 206B may be separated; however may be integrated.

In the exemplary embodiment of the present invention, the first and second terminals 104A and 104B may be symmetrically disposed about the center of the light emitting element 101, when the second main surface of the light emitting element 101 is viewed in a planar manner, that is, in the case of viewing from the bottom of the light emitting element 101 based on FIG. 1. As the first and second terminals 104A and 104B are symmetrical, it is unnecessary to indicate the positive and negative poles thereof in the case of mounting the light emitting device 100 on a substrate or the like, and mounting errors may be reduced. In this case, the first and second terminals 104A and 104B may be properly arranged so as to have various shapes besides that shown in FIG. 3.

The wavelength converting part 102 may function to convert the wavelength of light emitted from the light emitting element 101 to another wavelength, may be formed on at least a partial light emitting surface of the light emitting element 101, that is, on the upper surface thereof, in the form of a thin film. Since the wavelength converting part 102 is provided in the form of a thin film to thereby have a relatively uniform shape and thickness, the color dispersion of white light may be minimized with respect to the emitting direction of the light, and furthermore, color dispersion between different devices may be reduced.

Meanwhile, in order to perform light converting functions, the wavelength converting part 102 may have a wavelength conversion material, such as phosphors or quantum dots. In this case, the wavelength conversion material may have a plate structure made only of the wavelength conversion material (for example, a ceramic converter body), or a film structure formed by dispersing the wavelength conversion material on a silicon resin. In this case, when the wavelength conversion material is a phosphor and blue light is emitted from the light emitting element 101, a nitride phosphor made of MAlSiNx:Re (1≦x≦5), a phosphor made of MD:Re, or the like may be used as a red phosphor. Here, M is at least one selected from Ba, Sr, Ca and Mg, D is at least one selected from S, Se and Te, and Re is at least one selected from Eu, Y, La, Ce, Nd, Pm, Sm, Gd, Tb, Dy, Ho, Er, Tm, Yb, Lu, F, Cl, Br and I. In addition, a silicate phosphor made of M₂SiO₄:Re, a phosphor made of MA₂D₄:Re, a phosphor made of β-SiAlON:Re, an oxide phosphor made of MA′₂O₄:Re′, or the like may be used as a green phosphor. Here, M is at least one element selected from Ba, Sr, Ca and Mg, A is at least one selected from Ga, Al and In, D is at least one selected from S, Se and Te, A′ is at least one selected from Sc, Y, Gd, La, Lu, Al and In, Re is at least one selected from Eu, Y, La, Ce, Nd, Pm, Sm, Gd, Tb, Dy, Ho, Er, Tm, Yb, Lu, F, Cl, Br and I, and Re′ is at least one selected from Ce, Nd, Pm, Sm, Tb, Dy, Ho, Er, Tm, Yb, F, Cl, Br and I.

Moreover, the quantum dot may be a nano-crystalline particle formed of a core and a shell, and the size of the core may be in the range of 2 to 100 nm. The quantum dot may be used as a fluorescent material emitting various colors, such as blue (B), yellow (Y), green (G) and red (R) by adjusting the size of the core thereof. The hetero-junction of at least two kinds of semiconductors among a group II-VI compound semiconductor (ZnS, ZnSe, ZnTe, CdS, CdSe, CdTe, HgS, HgSe, HgTe, MgTe or the like), a group III-V compound semiconductor (GaN, GaP, GaAs, GaSb, InN, InP, InAs, InSb, AlAs, AlP, AlSb, AlS or the like), or a group IV semiconductor (Ge, Si, Pb or the like) is performed, thereby forming the structure of core and shell constituting the quantum dot. In this case, an organic ligand using a material, such as oleic acid or the like, may be formed on the shell outside of the quantum dot, in order to terminate molecular bonds on a shell surface, inhibit the aggregation of quantum dots and improve dispersibility in a resin such as a silicon resin, an epoxy resin or the like, or enhance phosphor capabilities.

As shown in FIG. 1, the reflecting part 103 may cover at least the sides of the light emitting element 101 and the wavelength conversion part 102 and serve to guide the light emitted from the light emitting element 101 upwardly. Especially, the reflecting part 103 may be formed on the sides of the wavelength conversion part 102, as well as the light emitting element 101, thereby contributing to the improvement of luminous efficiency. In other words, as shown in FIG. 4, the reflecting part 103 may guide light emitted from the sides (‘side emitted light’) which does not substantially contribute to luminance, upwardly. In addition, the reflecting part 103 may cover the lower surface of the light emitting element 101, that is, cover the second main surface having the first and second terminals 104A and 104B, and further cover the sides of the first and second terminals 104A and 104B, thereby allowing the light to be concentrated and emitted upwardly. Moreover, as will be described later, in the case in which the reflecting part 103 is formed by molding, one surface of the wavelength conversion part 102 and one surface of the reflecting part 103 may form a co-plane. Further, one surfaces of the first and second terminals 104A and 104B and one surface of the reflecting part 103 may form a co-plane.

The reflecting part 103 may be made of any material capable of reflecting light, in order to perform a light reflecting function; however, the reflecting part 103 may be made of an electrical insulating material in view of the fact that the reflecting part 103 is in contact with the light emitting element 101 and the first and second terminals 104A and 104B. For example, the reflecting part 103 may include a resin having a low refractive index and a reflective filler dispersed in the resin. In this case, the reflective filler may be made of a light reflective oxide, such as TiO₂, SiO₂ or the like. In addition, a silicon resin or an epoxy resin may be used as the resin forming the reflecting part 103. A refractive index thereof may be low, for example, on the level of 1.5 or less, in order to increase reflective performance.

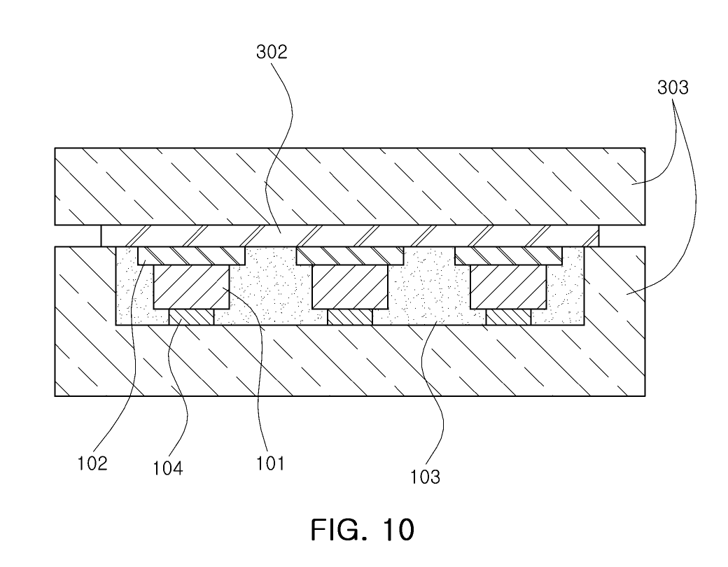

Hereinafter, a method of manufacturing the light emitting device having the structure as above will be exemplarily explained. FIGS. 5 through 11 are cross sectional views of processes schematically showing a method of manufacturing a light emitting device according to the exemplary embodiment of the present invention. In the case of the manufacturing method according to the exemplary embodiment, first, the terminal 104 is formed on a light emitting laminate 101, as shown in FIG. 5. The laminate 101 may have a structure in which the light emitting element explained in FIG. 1 is provided connectedly in plural. Each light emitting element may be obtained by dividing the light emitting laminate 101 into light emitting element units. In this case, the terminal 104 may be provided for each light emitting element (three light emitting elements in the case of the exemplary embodiment) through a masking process, a plating process, or the like. Although the first and second terminals are not individually described in FIG. 5, unlike FIG. 1, it may be understood that the separate first and second terminals may provided. Then, as shown in FIG. 6, the light emitting laminate 101 is divided into light emitting element units. Prior to the division process, a lapping process reducing the thickness of the light emitting laminate 101 may be conducted. The dividing of the light emitting laminate into the individual light emitting elements 101 may be performed by a breaking process in which the light emitting laminate is partially cut off, followed by the expanding of a separation tape.

Meanwhile, the preparing of the wavelength converting part may be performed simultaneously with or separately from preparing the light emitting elements 101. More specifically, as shown in FIG. 7, a film for wavelength conversion, for example, a phosphor film is molded on a carrier film 301, and then subjected to dicing into individual light emitting element units, whereby one or more wavelength converting parts 102 (three wavelength converting parts in the exemplary embodiment) may be provided to correspond to the individual light emitting elements on the carrier film 301. Thereafter, the wavelength converting parts 102 may be transferred to a UV sheet 302, which is to facilitate the separation of the wavelength converting parts 102 from the UV sheet 302, in the state in which the light emitting elements 101 are bonded to the wavelength converting parts 102 during a subsequent process. To this end, a curing process irradiating light to the UV sheet 302 after the transferring of the wavelength converting part 102 may be conducted.

Next, as shown in FIG. 9, one surface of the wavelength converting part 102 and one surface of the light emitting element 101 may be bonded. Though not illustrated, a light-transmitting adhesive may be applied to the bonding surface of the wavelength converting part 102, which may then be bonded to the surface of the light emitting element 101 obtained by the foregoing processes. Next, as shown in FIG. 10, the reflecting part 103 is formed, and more specifically, the reflecting part 103 may be formed by a process such as compression molding or the like after the disposition of the light emitting elements 101 within a molding device 303. In this case, the reflecting part 103 may be integrally formed with respect to the separate light emitting elements 101. As shown in FIG. 11, the reflecting part 103 may be divided into the individual units of the light emitting elements 101, thereby completing light emitting devices. Thereafter, the completed light emitting devices may be properly classified based on rank according to the characteristics of the emitted white light.

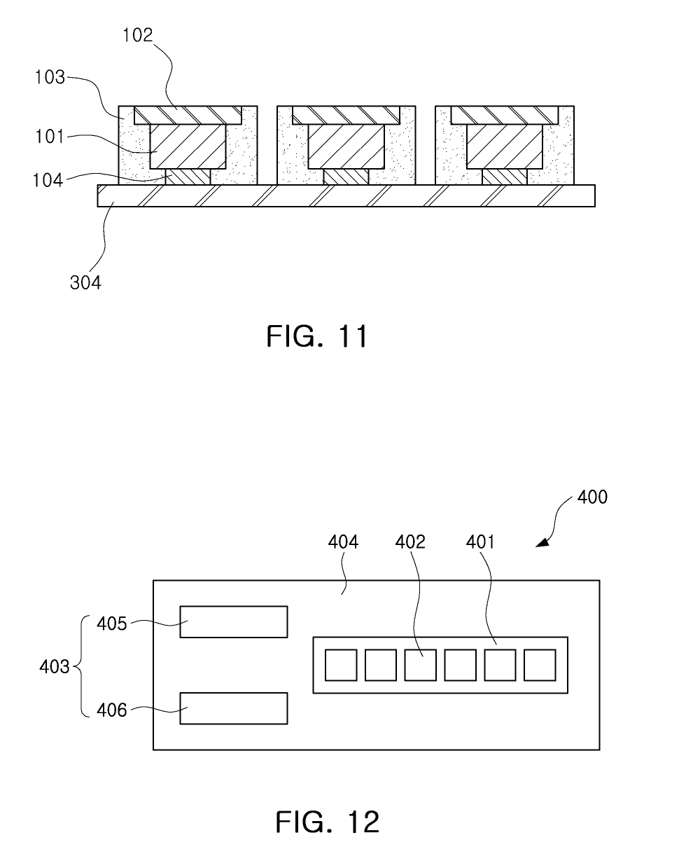

Meanwhile, the light emitting devices having the structures as above may be applied to various fields. FIG. 12 is a configuration diagram schematically showing an example of using the light emitting device according to the exemplary embodiment of the present invention. Referring to FIG. 12, an illuminating device 400 may include a light emitting module 401, a structure 404 in which the light emitting module 401 is disposed, and a power source supplying unit 403. In the light emitting module 401, one or more light emitting devices obtained by the foregoing processes may be disposed. In this case, the light emitting device 402 may mounted on a substrate in itself, or in the form of a package. The power source supplying unit 403 may include an interface 405 to which power is supplied, and a power source supply control unit 406 controlling power supplied to the light emitting module 401. In this case, the interface 405 may include a fuse blocking an overcurrent and an electromagnetic shielding filter shielding an electromagnetic interference signal.

The power source supply control unit 406 may include a rectifier converting an alternating current into a direct current, and a constant voltage controller converting the current into voltage suitable for the light emitting module 401, when the alternating current is inputted thereto as a power source. When the power source is a direct current source (for example, a battery) having a voltage level appropriate for the light emitting module 401, the rectifier and the constant voltage controller may be omitted. Moreover, when the light emitting module 401 may employ an element such as AC-LED, the alternating current may be directly supplied to the light emitting module 401, and in this case, the rectifier and the constant voltage controller may be omitted. Further, the power source supply control unit may control a color temperature or the like, thereby allowing for the presentation of lighting according to human sensitivity. In addition, the power source supplying unit 403 may include a feedback circuit device comparing the amount of light emitted from the light emitting device 402 with a predetermined light emitting amount, and a memory element in which information, such as a desirable level of luminance or color rendering properties is stored.

This illuminating device 400 maybe used as a backlight unit for a display apparatus such as a liquid crystal display including an image panel, or the like, or may be used as an indoor lighting device such as a lamp, a flat lighting device or the like or an outdoor lighting device such as a load lamp, a signboard, a sign or the like. Furthermore, this illuminating device 400 may be used for lighting devices for various transportation vehicles, for example, an automobile, a ship, an aircraft or the like. Further, this illuminating device 400 may be used for home appliances such as a TV, a refrigerator or the like or medical instruments.

As set forth above, according to exemplary embodiments of the invention, there is provided a light emitting device in which the color dispersion of white light is minimized with respect to the emitting direction of light, whereby the white light exhibits uniform characteristics, and further, light emitting efficiency is improved.

According to exemplary embodiments of the invention, there is also provided a method of effectively manufacturing the light emitting device.

While the present invention has been shown and described in connection with the exemplary embodiments, it will be apparent to those skilled in the art that modifications and variations can be made without departing from the spirit and scope of the invention as defined by the appended claims.

What is claimed is:

1. A light emitting device, comprising:
a light emitting element having first and second main surfaces opposed to each other;
a wavelength converting part formed on the first main surface of the light emitting element;
first and second terminals formed on the second main surface of the light emitting element; and
a reflecting part formed to cover at least sides of the light emitting element and sides of the wavelength converting part.

2. The light emitting device of claim 1, wherein the reflecting part is formed to cover the second main surface of the light emitting element.

3. The light emitting device of claim 1, wherein the reflecting part is formed to cover sides of the first and second terminals.

4. The light emitting device of claim 1, wherein the wavelength converting part has a thin film shape.

5. The light emitting device of claim 1, wherein one surface of the wavelength conversion part and one surface of the reflecting part form a co-plane.

6. The light emitting device of claim 1, wherein one surfaces of the first and second terminals and one surface of the reflecting part form a co-plane.

7. The light emitting device of claim 1, wherein the first and second terminals are symmetrically disposed about the center, when the second main surface is viewed in a planar manner.

8. The light emitting device of claim 1, wherein the reflecting part includes a resin and a reflective filler dispersed in the resin.

9. A method of manufacturing a light emitting device, comprising:
forming first and second terminals on one surface of a light emitting element;
forming a wavelength converting part on the other surface of the light emitting element, the other surface being disposed to be opposite to the first and second terminals; and
forming a reflecting part to cover sides of the light emitting element and sides of the wavelength converting part.

10. The method of claim 9, wherein the forming of the first and second terminals on one surface of the light emitting element includes forming each of the first and second terminals for individual light emitting element units on one surface of a light emitting laminate, and dividing the light emitting laminate into individual light emitting element units.

11. The method of claim 10, wherein the forming of the wavelength converting part includes forming one wavelength converting part for each light emitting element unit and attaching the light emitting element unit to the wavelength converting part corresponidng to the light emitting element unit.

12. The method of claim 11, wherein the forming of one wavelength converting part for each light emitting element unit includes cutting the wavelength converting part integrally formed into each light emitting element unit and transferring the cut wavelength converting part onto a UV sheet.

13. The method of claim 10, wherein the forming of the reflecting part includes integrally forming the reflecting part with respect to the individual light emitting element units and dividing the reflecting part into individual light emitting element units.
